(19) United States
(12) Patent Application Publication
(10) Pub. No.: US 2025/0343188 A1
(43) Pub. Date: Nov. 6, 2025

(54) ARRANGING BOND PADS TO REDUCE IMPACT ON PASSIVE DEVICES

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei City (TW); Ta Hao Sung, Hsinchu (TW); Gao-Long Wu, Hsinchu City (TW); Shin-Jiun Fu, Hsinchu City (TW)

(21) Appl. No.: 19/268,042

(22) Filed: Jul. 14, 2025

Related U.S. Application Data
(63) Continuation of application No. 18/402,944, filed on Jan. 3, 2024.
(60) Provisional application No. 63/584,561, filed on Sep. 22, 2023.

(51) Int. Cl. H01L 23/00; H01L 23/498; H01L 23/522; H01L 25/00; H01L 25/065; H01L 25/18

(52) U.S. Cl. CPC H01L 24/08; H01L 23/49822; H01L 23/5227; H01L 24/06; H01L 25/18; H01L 25/50; H01L 25/0652; H01L 25/0655; H01L 25/0657; H01L 2224/0603; H01L 2224/08225; H01L 2924/1431; H01L 2924/1436

(57) ABSTRACT

A method includes forming a function circuit on a semiconductor substrate of a device die, wherein the function circuit is in a functional circuit zone of the device die, forming a passive device over the semiconductor substrate, wherein the passive device is in a passive device zone of the device die, forming a first plurality of bond pads in the functional circuit zone and at a surface of the device die, wherein the first plurality of bond pads have a first pattern density; and forming a second plurality of bond pads in the passive device zone and at the surface of the device die. The second plurality of bond pads have a second pattern density lower than the first pattern density.

### PRIORITY CLAIM AND CROSS-REFERENCE

This application is a continuation of U.S. patent application Ser. No. 18/402,944, filed Jan. 3, 2024, which application claims the benefit of the following provisionally filed U.S. Patent Application No. 63/584,561, filed on Sep. 22, 2023, and entitled “SEMICONDUCTOR DIE WITH OPTIMIZED ARRANGEMENT OF BOND METALS;” which applications are hereby incorporated herein by reference.

### BACKGROUND

Semiconductor chips may include active devices and passive devices such as transistors, capacitors, inductors, or the like. In a semiconductor chip, the transistors are formed on the surface of a semiconductor substrate of the semiconductor chip. The passive devices may be formed over the semiconductor chip. Bond pads may be formed over the passive devices and active devices, and may be used for bonding to another package component such as a semiconductor chip, an interposer, a package substrate, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a device die including a passive device and overlying bond pads in accordance with some embodiments.

FIG. 2 illustrates a top view of a device die including a passive device and overlying bond pads in accordance with some embodiments.

FIG. 3 illustrates a top view of a passive device region, a transition region, and a function circuit region in accordance with some embodiments.

FIG. 4 illustrates a top view of a passive device region in accordance with some embodiments.

FIG. 5 illustrates a top view of transition region with gradient pattern densities in accordance with some embodiments.

FIG. 6 illustrates a cross-sectional view of a portion of a device die including a passive device, a transition zone, a functional circuit zone, and the overlying bond pads in accordance with some embodiments.

FIG. 7 illustrates a plurality of distribution patterns of bond pads in passive device zones in accordance with some embodiments.

FIGS. 8 and 9 illustrate the possible top-view shapes of bond pads in passive device zones in accordance with some embodiments.

FIG. 10 illustrates a plurality of distribution patterns of cluster bond pads in passive device zones in accordance with some embodiments.

FIG. 11 illustrates a plurality of distribution patterns of bond pads in transition zones in accordance with some embodiments.

FIGS. 12 and 13 illustrate the cross-sectional view shapes of redistribution lines in accordance with some embodiments.

FIG. 14 illustrates a cross-sectional view of two bonded device dies in accordance with some embodiments.

FIGS. 15-26 illustrate the cross-sectional views of intermediate stages in the formation of a top structure of a device die in accordance with some embodiments.

FIGS. 27-35 illustrate the cross-sectional views of some structures that adopt the embodiments in accordance with some embodiments.

FIG. 36 illustrates a process flow for forming a top structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A device die including passive devices and optimized arrangement of bond pads and the method of forming the same are provided. In accordance with some embodiments, a passive device such as an inductor is formed in a passive device zone. Functional circuits including active devices are formed in a functional circuit zone. A transition zone is formed to separate the passive device zone from the functional circuit zone. Bond pads are formed in passive device zone and transition zone (in addition to the functional circuit zone) to reduce pattern loading effect. To minimize the adverse effect of the bond pads in the passive device zone to the performance of the passive device and circuits, the pattern density in the passive device zone is lower than that in the functional circuit zone. The pattern density in the transition zone may further be higher than that in the passive device zone and lower than that in the functional circuit zone to mitigate the pattern density difference between the passive device zone and the functional circuit zone.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

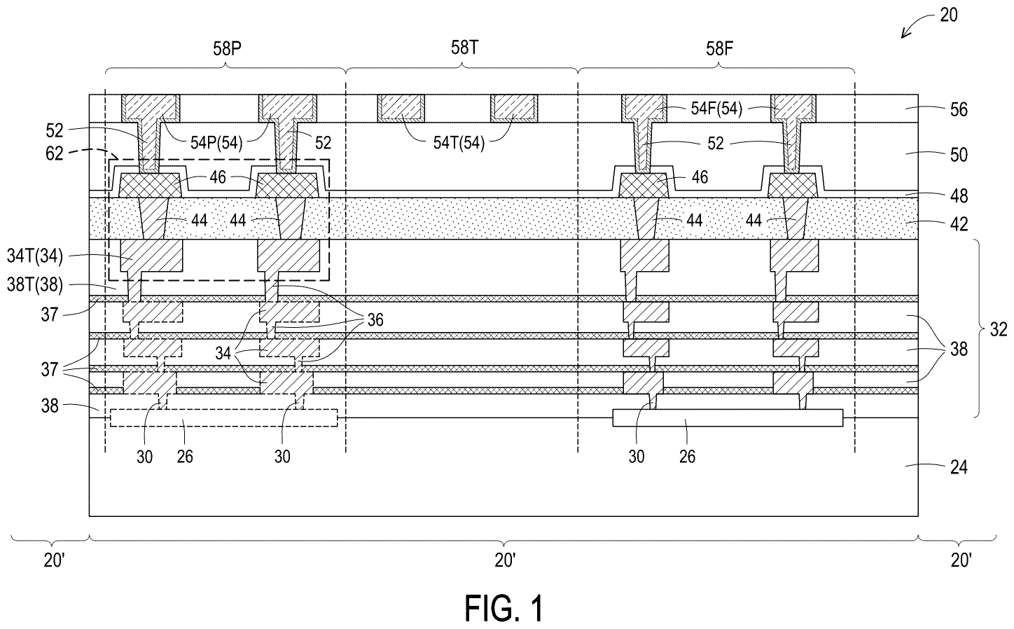

FIG. 1 illustrates a cross-sectional view of wafer 20. In accordance with some embodiments, wafer 20 is or may comprise a device wafer including active devices and passive devices, which are represented as integrated circuit devices 26. Wafer 20 may include a plurality of chips (device dies) 20′ therein, with one of device dies 20′ being illustrated.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, silicon germanium, carbon-doped silicon, or a III-V compound semiconductor such as GaAsP, AlInAs, AlGaAs, GaInAs, GaInP, GaInAsP, or the like. Shallow Trench Isolation (STI) regions (not shown) may be formed in semiconductor substrate 24 to isolate the active regions in semiconductor substrate 24.

In accordance with some embodiments, wafer 20 includes integrated circuit devices 26, which are formed on the top surface of semiconductor substrate 24. Integrated circuit devices 26 may include Complementary Metal-Oxide Semiconductor (CMOS) transistors, resistors, capacitors, diodes, and the like in accordance with some embodiments. The details of integrated circuit devices 26 are not illustrated herein.

Interconnect structure 32 is formed over integrated circuit devices 26, and includes ILD 28 and contact plugs 30. Inter-Layer Dielectric (ILD) 28 fills the spaces between the gate stacks of transistors (not shown) in integrated circuit devices 26. In accordance with some embodiments, ILD 28 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 28 may be formed using spin-on coating. In accordance with alternative embodiments, ILD 28 may also be formed using a deposition method such as Flowable Chemical Vapor Deposition (FCVD), Plasma Enhanced Chemical Vapor Deposition (PECVD), Low Pressure Chemical Vapor Deposition (LPCVD), or the like.

Contact plugs 30 are formed in ILD 28, and are used to electrically connect integrated circuit devices 26 to overlying metal lines and vias. In accordance with some embodiments, contact plugs 30 are formed of or comprise a conductive material selected from tungsten, aluminum, copper, titanium, tantalum, titanium nitride, tantalum nitride, alloys therefore, and/or multi-layers thereof. The formation of contact plugs 30 may include forming contact openings in ILD 28, filling a conductive material(s) into the contact openings, and performing a planarization process (such as a Chemical Mechanical Polish (CMP) process or a mechanical grinding process) to level the top surfaces of contact plugs 30 with the top surface of ILD 28.

Interconnect structure 32 further includes metal lines 34 and vias 36, which are formed in dielectric layers 38 (also referred to as Inter-metal Dielectrics (IMDs)) and etch stop layers 37. The metal lines at a same level are collectively referred to as a metal layer hereinafter. In accordance with some embodiments, interconnect structure 32 includes a plurality of metal layers including metal lines 34 that are interconnected through vias 36. Metal lines 34 and vias 36 may be formed of copper or copper alloys, and can also be formed of other metals such as tungsten, nickel, or the like.

In accordance with some embodiments, dielectric layers 38 are formed of low-k dielectric materials. The dielectric constants (k values) of the low-k dielectric materials may be lower than about 3.5 or 3.0, for example. Dielectric layers 38 may comprise a carbon-containing low-k dielectric material, Hydrogen SilsesQuioxane (HSQ), MethylSilsesQuioxane (MSQ), or the like. Etch stop layers 37 are formed underlying the respective dielectric layers 38, and may be formed of or comprise aluminum nitride, aluminum oxide, silicon oxycarbide, silicon nitride, silicon carbide, silicon oxynitride, or the like, or multi-layers thereof.

The formation of metal lines 34 and vias 36 in dielectric layers 38 may include single damascene processes and/or dual damascene processes. In a single damascene process for forming a metal line or a via, a trench or a via opening is first formed in one of dielectric layers 38, followed by filling the trench or the via opening with a conductive material. A planarization process such as a CMP process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. Conductive materials are then filled into the trench and the via opening to form a metal line and a via, respectively. The conductive materials may include a diffusion barrier layer and a copper-containing metallic material over the diffusion barrier layer. The diffusion barrier layer may include titanium, titanium nitride, tantalum, tantalum nitride, or the like.

Metal lines 34 include top conductive (metal) features (denoted as 34T) such as metal lines, metal pads, or vias in a top dielectric layer (denoted as dielectric layer 38T), which is the top layer of dielectric layers 38. In accordance with some embodiments, dielectric layer 38T is formed of a low-k dielectric material similar to the material of lower ones of dielectric layers 38. The metal features 34T in the top dielectric layer 38T may also be formed of copper or a copper alloy, and may have a dual damascene structure or a single damascene structure.

Passivation layer 42 (sometimes referred to as passivation-1 or pass-1) is formed over interconnect structure 32. In accordance with some embodiments, passivation layer 42 is formed of a non-low-k dielectric material having a dielectric constant equal to or greater than the dielectric constant of silicon oxide. Passivation layer 42 may be formed of or comprise an inorganic dielectric material, which may include a material selected from, and is not limited to, Undoped Silicate Glass (USG), silicon nitride (SiN), silicon oxide (SiO₂), silicon oxy-nitride (SiON), silicon oxy-carbide (SiOC), or the like, combinations thereof, and/or multi-layers thereof. In accordance with some embodiments, the top surfaces of top dielectric layer 38T and metal lines/pads 34T are level with one another. Accordingly, passivation layer 42 may be a planar layer.

In accordance with some embodiments, vias 44 are formed in passivation layer 42 to electrically connect to the underlying top metal features 34T. Redistribution Lines (RDLs) 46, which may include metal lines and metal pads, are further formed over vias 44. In accordance with some embodiments, RDLs 46 comprise aluminum, aluminum copper, or the like. Passivation layer 48 (sometimes referred to as passivation-2 or pass-2) is also formed, and may extend on the sidewalls and the top surfaces of RDLs 46. Passivation layer 48 may be formed of or comprise silicon oxide, silicon nitride, or the like, or multi-layers thereof.

In accordance with some embodiments, dielectric layer 50 is formed. Dielectric layer 50 may be planarized, and is referred to as a planarization layer. In accordance with some embodiments, dielectric layer 50 may be formed by dispensing a polymer in a flowable form, and then curing polymer layer 50. Dielectric layer 50 may also be formed through deposition. Dielectric layer 50 is patterned to expose RDLs 46. Dielectric layer 50, when formed of polymer, may be formed of or comprise polyimide, polybenzoxazole (PBO), or the like. Alternatively, dielectric layer 50 may be formed of or comprise an inorganic dielectric material such as silicon oxide, silicon nitride, silicon oxynitride, or the like.

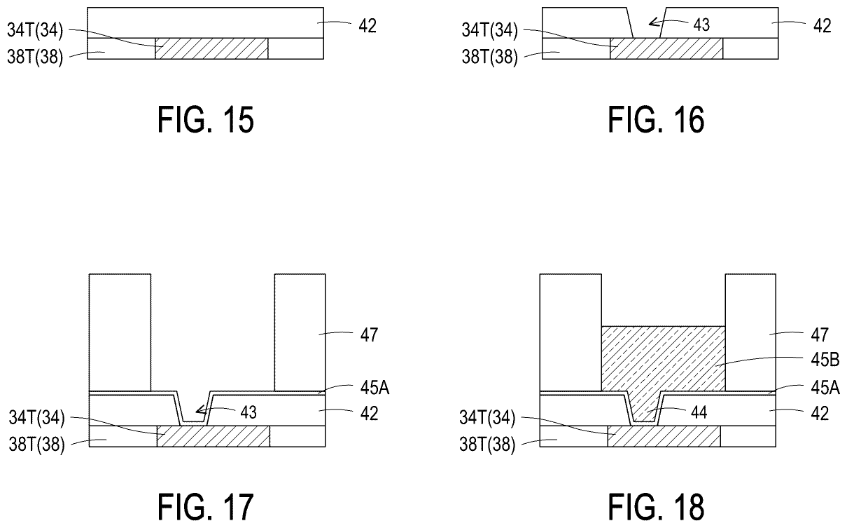

Dielectric layer 56 is formed over dielectric layer 50. Bond pads 54 and bond vias 52 are formed in dielectric layer 56 to electrically connect to the underlying RDLs 46. The detailed structures, materials, and formation processes of bond vias 52, bond pads 54, and dielectric layer 56 are discussed referring to the processes as shown in FIGS. 15 through 26.

In accordance with some embodiments, device die 20′ includes functional circuit zone 58F, which include functional circuits 26 therein. The functional circuits 26 may include active devices such as transistors therein. Bond pads 54F, which are parts of bond pads 54, are formed at the surface of device die 20′ and in functional circuit zone 58F. At least some of bond pads 54F are electrically connected to the integrated circuit devices 26. There may be, or may not be, dummy bond pads (also denoted as 54F) in functional circuit zone 58F. The dummy bond pads do not have electrical functions, and may be electrically floating (when the device die 20′ is powered up). In accordance with some embodiments, all bond pads 54F overlap the functional circuits 26 in functional circuit zone 58F.

Device die 20′ further includes passive device zone 58P, which includes passive device 62 therein. Bond pads 54P, which are parts of bond pads 54, are formed at the surface of device die 20′ and passive device zone 58P. The passive device 62 may be or may comprise an inductor, a capacitor, or the like. In FIG. 1, passive device 62 is illustrated schematically. In accordance with some embodiments, the passive device 62 includes a plurality of portions of the RDLs 46, vias 44, and the underlying metal lines 34T, which are interconnected to form coils (spirals) when passive device 62 includes an inductor. In accordance with other embodiments, the passive device 62 may be formed in RDLs 46 and does not include portions of the underlying top metal layer. In accordance with yet other embodiments, the entirety of the passive device 62 may be formed in lower metal layers including and possibly under the top metal layer.

In accordance with some embodiments, under passive device 62, there are integrated circuit devices 26, metal lines 34, and/or vias 36 formed in passive device zone 58P, which integrated circuit devices 26 may be electrically connected to the overlying bond pads 54P. In accordance with some embodiments, all bond pads 54P overlap the functional circuits 26 in the passive device zone 58P. In accordance with alternative embodiments, no integrated circuit devices 26, metal lines 34, and/or vias 36 are formed underlying passive device 62. Accordingly, the integrated circuit devices 26, metal lines 34, and/or vias 36 in passive device zone 58P are illustrated as being dashed to indicate that these features may be, or may not be formed.

In accordance with some embodiments, depending on the number of passive device(s) 62, the number of terminals of passive device(s) 62, the number of bond pads 54P, and the connection scheme of passive devices 62 to the integrated circuit devices 26, there may be, or may not be, dummy bond pads (also denoted as 54P) in passive device zone 58P. In accordance with some embodiments, all bond pads 54P are connected to the passive device(s) 62 and/or the underlying integrated circuit devices 26. In accordance with alternative embodiments, all bond pads 54P are dummy bond pads. In accordance with yet alternative embodiments, some of bond pads 54P are connected to the passive device(s) 62 and/or the underlying integrated circuit devices 26, while other bond pads 54P are dummy bond pads.

Transition zone 58T is located between functional circuit zone 58F and passive device zone 58P. In accordance with some embodiments, transition zone 58T includes bond pads 54T (which are also parts of bond pads 54). Bond pads 54T may be dummy bond pads. In accordance with some embodiments, some or all of bond pads 54T do not have underlying vias 52. In accordance with some embodiments, no integrated circuit devices 26, metal lines 34, and/or vias 36 are formed in transition zone 58T and under bond pads 54T.

In accordance with alternative embodiments, there may also be some integrated circuit devices 26, metal lines 34, and/or vias 36 formed in transition zone 58T and under bond pads 54T. In accordance with yet alternative embodiments, there may be some dummy metal lines 34 and/or vias 36 (not shown) in transition zone 58T and under bond pads 54T, with the dummy metal lines 34 and/or vias 36 being used to reduce the pattern loading effect in the formation of metal lines 34 and/or vias 36, respectively. These dummy metal lines 34 and/or vias 36 may be electrically floating, and may be electrically connected to or electrically disconnected from bond pads 54T.

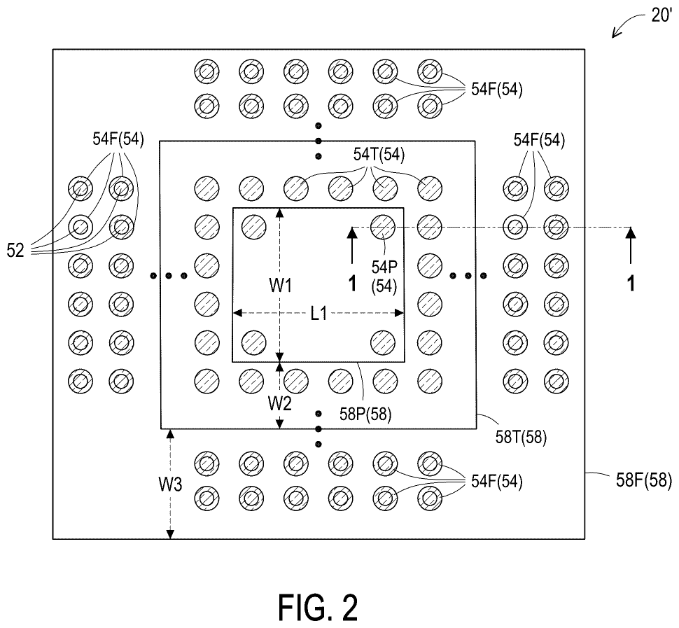

FIG. 2 illustrates a top view of a portion of device die 20′ in accordance with some embodiments. The passive device zone 58P may be encircled by transition zone 58T. Transition zone 58T separates passive device zone 58P from functional circuit zone 58F, which may further encircle transition zone 58T. The cross-sectional view shown in FIG. 1 may be obtained from the cross-section 1-1 in FIG. 2.

In each of the zones 58F, 58T, and 58P, the respective bond pads 54 have a pattern density, which is calculated as the ratio of the total area of bond pads 54 in the respective zone to the total chip area of the zone. Accordingly, the bond pads 54F in functional circuit zone 58F have pattern density PD_{54F}, the bond pads 54T in transition zone 58T have pattern density PD_{54T}, and the bond pads 54p in passive device zone 58P have pattern density PD_{54P}. Furthermore, since the pattern density of bond pads 54 have greater fluctuation when calculated for smaller chip areas, the pattern density of bond pads 54 are defined as being calculated in a minimum chip area with both of length and width being equal to or greater than 50 μm. In accordance with some embodiments, the pattern density of PD_{54P} may be calculated based on the entire area of the passive device zone 58P, and the pattern density of PD_{54T} may be calculated based on the entire area of the transition zone 58T. The pattern density of PD_{54F} may be calculated based a ring-shaped chip area with a width W3 greater than 1.5 μm, or the entire area of the functional circuit zone 58F.

The bond pads 54P directly over passive device 62 (FIG. 1) may adversely impact the performance of the passive device 62 and the circuit that are connected to the passive device 62. To reduce the adverse impact, the pattern density PD_{54P} of passive device zone 58P is designed to be small, and is smaller than pattern density PD_{54F} of functional circuit zone 58F. Reducing the pattern density PD_{54P} to be smaller than pattern density PD_{54F}, however, worsens the pattern loading effect, for example, in the planarization process (discussed referring to FIG. 26) for forming bond pads 54.

To solve this problem, the pattern density PD_{54T} in transition zone 58T is designed to be smaller than pattern density PD_{54F} and greater than the pattern density PD_{54P}. This may mitigate the pattern loading effect, and may reduce the possibility of non-bond issues. In accordance with some embodiments, the pattern density PD_{54P} in the passive device zone 58P may be in the range between about 0 percent (when no bond pad is in the passive device zone 58P) and about 6 percent. The pattern density PD_{54T} in the transition zone 58T may be in the range between about 0.5 percent and about 2 percent. The pattern density PD_{54F} in the functional circuit zone 58F may be in the range between about 5 percent and about 25 percent. The ratio PD_{54P}/PD_{54T} may be in the range between about 0 and about 0.3, and the ratio PD_{54T}/PD_{54F} may be in the range between about 0.3 and about 1. The ratio PD_{54P}/PD_{54F} may be smaller than about 0.3, and may be in the range between about 0 and about 0.3.

In accordance with some embodiments, the length L1 and width W1 of passive device zone 58P may be in the range between about 3 μm and about 3,000 μm. The width W2 of a ring-shaped transition zone 58T may be in the range between about 2 μm and about 40 μm. The width W3 of a ring-shaped functional circuit zone 58F may be in the range between about 3 μm and about 3,000 μm.

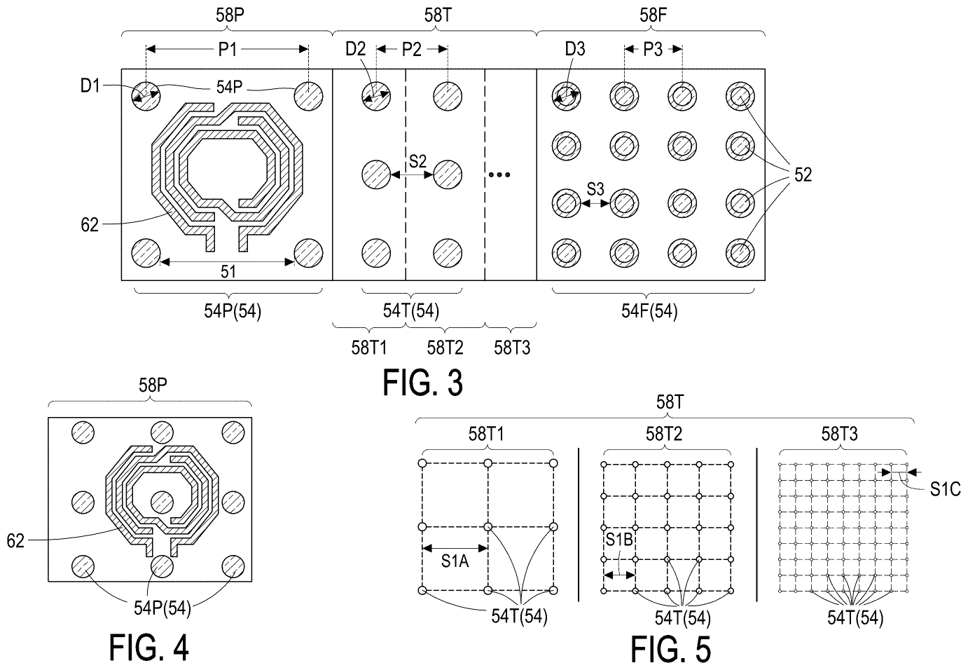

FIG. 3 illustrates an example top view of passive device zone 58P, transition zone 58T, and functional circuit zone 58F and the corresponding bond pads 54P, 54T, and 54F in accordance with some embodiments. An example inductor 62 is also illustrated. As shown in FIG. 3, the spacing S1 of bond pads 54P may be equal to or greater than the spacing S2 of bond pads 54T, and/or the spacing S2 of bond pads 54T may be equal to or greater than the spacing S3 of bond pads 54F. The diameter D1 of bond pads 54P may also be equal to or smaller than the diameter D2 of bond pads 54T, and/or the diameter D2 of bond pads 54T may be equal to or smaller than the diameter D3 of bond pads 54F. Accordingly, the difference in the pattern densities may be achieved through different spacings (or pitches) and/or different lateral dimensions (diameters or lengths and widths) of the bond pads 54P, 54T, and 54F. In accordance with some embodiments, diameters D1, D2, and D2 may range from about 0.5 μm to about 20 μm.

In accordance with some embodiments, the bond pads 54T in transition zone 58T may include a plurality of columns of bond pads, for example, greater than about 5 or 10 columns of bond pads. Accordingly, as may be realized from FIGS. 2 and 3 in combination, the bond pads 54T may be aligned to a plurality of rings, with the outer rings encircling the respective inner rings. The bond pads 54T aligning to a same ring may be referred to a bond pad ring. Bond pads 54F in functional circuit zone 58F may also include a plurality of (for example, more than 5 or 10) bond pad rings.

FIG. 4 illustrates an example top view of passive device zone 58P in accordance with some embodiments. The passive device zone 58P in accordance with these embodiments may have a greater number of bond pads 54P than the embodiments in FIG. 3. Furthermore, some of bond pads 54P may overlap the passive device 62 and/or the underlying integrated circuit 26 (if any), while in the embodiments in FIG. 3, the bond pads 54P may form a rectangular pattern encircling passive device 62, with the bond pads 54P located in locations close to, but not overlapping passive device 62 and/or the underlying integrated circuit devices 26.

In accordance with some embodiments, all of the bond pads 54P overlap passive device 62 and/or the underlying integrated circuit devices 26. In accordance with alternative embodiments, bond pads 54P may include the bond pads that overlap passive device 62 and/or the underlying integrated circuit devices 26, and may or may not include a ring of bond pads that do not overlap, and encircles the passive device 62 and/or the underlying integrated circuit devices 26 in the top view.

In accordance with some embodiments, the bond pads 54T in transition zone 54T are distributed uniformly with a uniform spacing, and hence a uniform pattern density. In accordance with alternative embodiments, the bond pads 54T in transition zone 54T have a gradient spacing and hence a gradient pattern density. For example, FIG. 3 uses dashed lines to mark a plurality of sub zones 58T1, 58T2, and 58T3 (or more) of transition zone 58T. The dashed lines indicate that the pattern density of the bond pads 54T may be uniform, or may be gradient. In accordance with some embodiments, the number of sub zones may range from 2 to 20.

In accordance with some embodiments, the bond pads 54T in each of the sub zones (such as 58T1, 58T2, and 58T3) has a uniform pattern density and a uniform spacing. The pattern densities and the spacings of neighboring sub zones, however, are different from each other. To minimize the patter loading effect, the bond pads 54T in the sub zones closer to the passive device zone 58P have lower pattern densities (and greater spacings and/or smaller lateral dimensions) than the bond pads 54T in the respective sub zones closer to functional circuit zone 54F. Alternatively stated, in the transition zone 58T, in the direction pointing from passive device zone 54P to the functional circuit zone 54F, the pattern densities may increase gradually, which means the diameters (lateral dimensions) of bond pads 54P may increase gradually, and/or the spacings may reduce gradually. For example, FIG. 5 illustrates three sub zones 58T1, 58T2, and 58T3 with spacings S1A, S1B, and S1C, respectively, with spacing S1B being smaller than spacing S1A, and spacing S1C being smaller than spacing S1B.

In accordance with some example embodiments in which there are three sub zones, the pattern densities in sub zones 58T1, 58T2, and 58T3 may be about 1%˜3%, about 8%˜15%, and about 18%˜22%, respectively. In accordance with alternative embodiments in which there are five sub zones, the pattern densities in sub zones 58T1, 58T2, 58T3, 58T4 (not shown), and 58T5 (not shown) may be about 1%˜3%, about 5%˜8%, about 9%˜13%, about 14%˜16%, and about 18%˜22%, respectively.

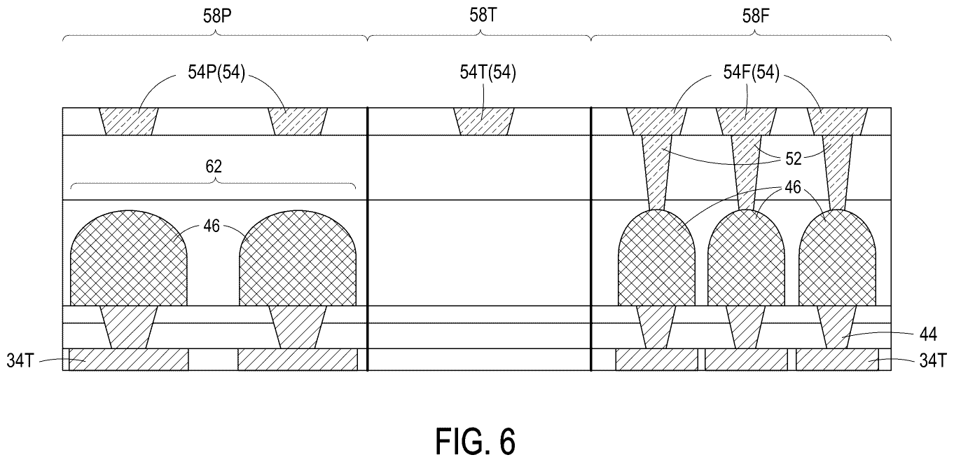

FIG. 6 illustrates the top features in three device zones 58P, 58T, and 58F in accordance with some embodiments. Some features such as the details of dielectric layers are not illustrated. RDLs 46, which form the passive device 62 in passive device zone 58P and the metal pads in the functional circuit zone 58F, may have rounded top surfaces, which are resulted due to the plating of copper in accordance with some embodiments.

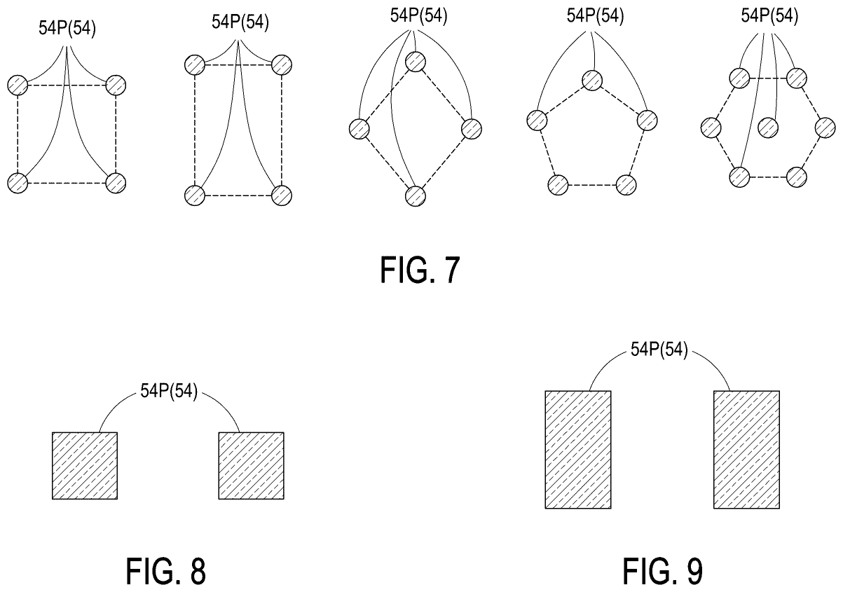

FIG. 7 illustrates some possible arrangements of the bond pads 54p in passive device zone 58P in accordance with some embodiments. For example, bond pads 54P may be on the nodes of and form a square array, a rectangle array, a diamond array, a pentagon array, a hexagon array, or the like, or any other regular or irregular pattern.

The top view shapes of bond pads 54 (54P, 54T, and/or 54F) may be any shape including and not limited to circles (FIG. 3), squares (FIG. 8), rectangles (FIG. 9), ovals, hexagons, octagons, or the like.

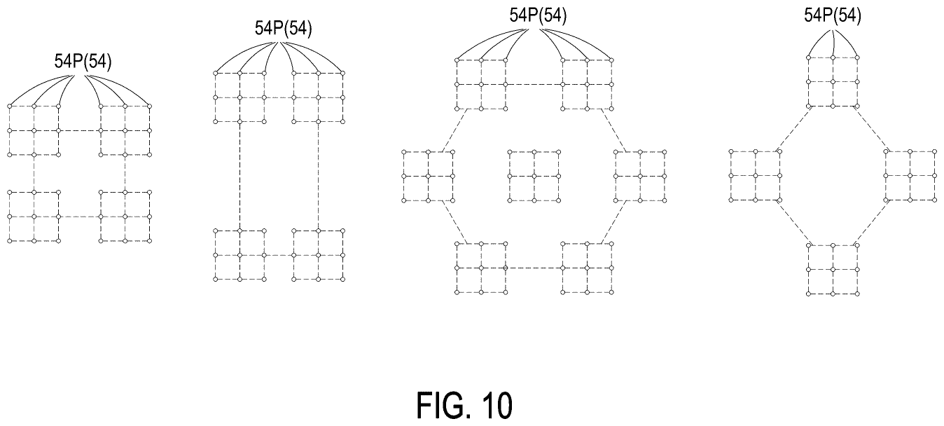

FIG. 10 illustrates some possible arrangements of the bond pads 54P in passive device zone 58P in accordance with some embodiments. The bond pads 54P may be arranged as a plurality of clusters, and the clusters are further arranged as regular or irregular patterns. The patterns of the plurality of clusters may be the same as each other or different from each other. As shown in FIG. 10, the clusters of bond pads 54P may be on the nodes of and form a square array, a rectangle array, a hexagon array, a diamond array, or the like, or any other regular or irregular pattern.

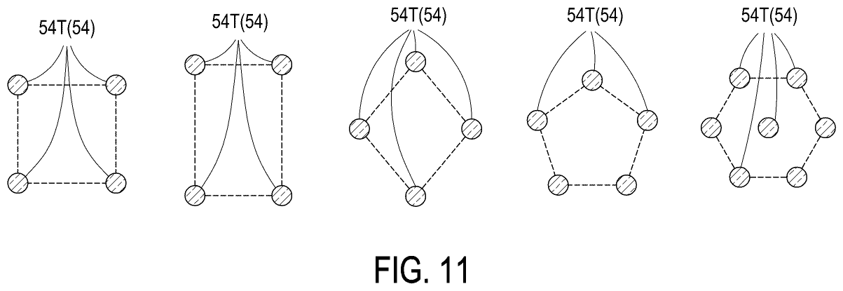

FIG. 11 illustrates some possible arrangements of the bond pads 54T in transition device zone 58T in accordance with some embodiments. For example, bond pads 54T may be on the nodes of and form a square array, a rectangle array, a diamond array, a pentagon array, a hexagon array, or the like, or any other regular or irregular pattern.

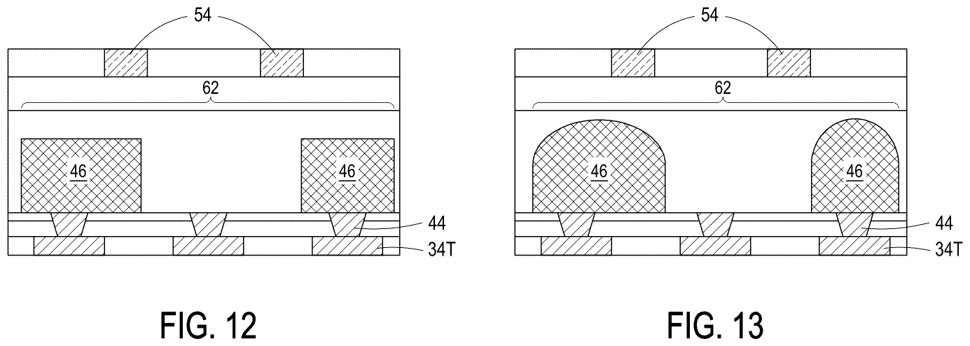

FIGS. 12 and 13 illustrate the cross-sectional shapes of RDLs 46, which form the passive device 62 in passive device zone 58P and the metal pads in the functional circuit zone 58F. In FIG. 12, RDLs 46 have planar top surfaces. This may be achieved by plating aluminum or aluminum copper. In FIG. 13, RDLs 46 have planar top surfaces. This may be achieved by plating copper in accordance with some embodiments.

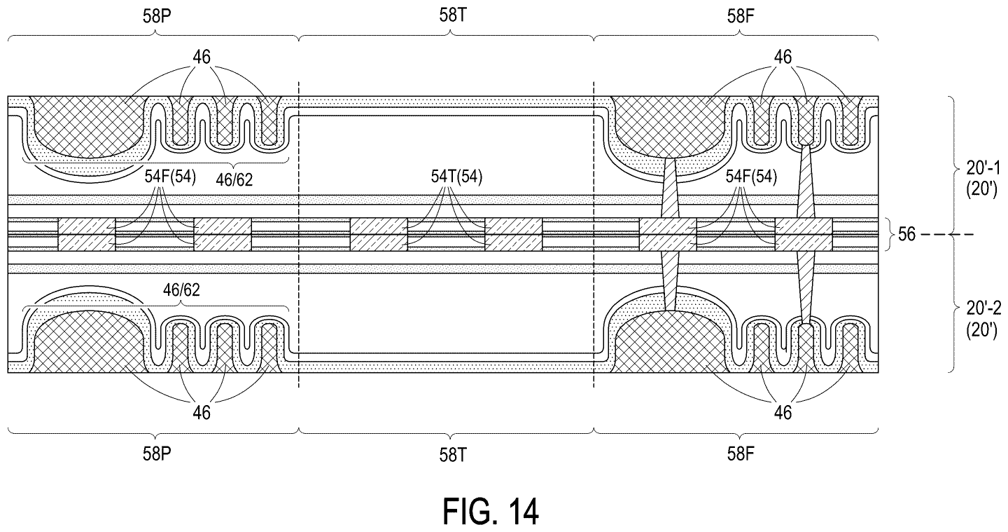

FIG. 14 illustrates the bonding of two device dies 20′ (including 20′-1 and 20′-2) to each other in accordance with some embodiments. The device die 20′-1 has bond pads corresponding to the bond pads of device die 20′-2. For example, after bonded, the passive device zone 58P, the transition zone 58T, and the functional circuit zone 58F of device die 20′-1 overlap the passive device zone 58P, the transition zone 58T, and the functional circuit zone 58F, respectively, of device die 20′-2. Furthermore, the positions and the sizes of the bond pads 54P, 54T, and 54F of device die 20′-1 may be the same as that of the bond pads 54P, 54T, and 54F of device die 20′-2. In accordance with some embodiments, the passive device 62 in device die 20′-1 is connected to the passive device 62 in device die 20′-2 in parallel or in series.

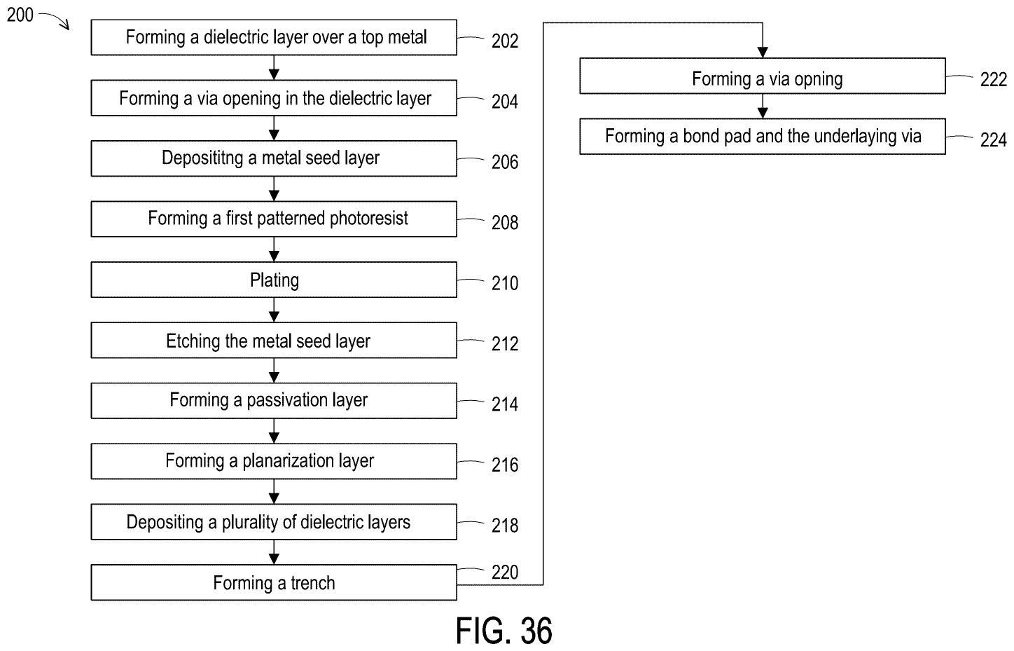

FIGS. 15 through 26 illustrate some example processes for forming the upper structure including passive device 62 (FIG. 1) in accordance with some embodiments. The corresponding processes are also reflected schematically in the process flow 200 as shown in FIG. 36. The lower structures in FIG. 1 is not illustrated, while the lower structures still exist underlying the illustrated portion. Some of the features shown in FIGS. 15-26 have been discussed referring to FIG. 1. The discussion of the processes in FIGS. 15-26 may be combined with the discussion referring to FIG. 1. It is appreciated that these processes are examples, and other applicable processes, structures, and materials may be used.

Referring to FIG. 15, top metal feature 34T is formed in top dielectric layer 38T. Passivation layer 42 is then deposited over top metal feature 34T. The respective process is illustrated as process 202 in the process flow 200 as shown in FIG. 36. Passivation layer may comprise silicon oxide or other materials as discussed referring to FIG. 1. FIG. 16 illustrates the formation of opening 43 in passivation layer 42 through an etching process, wherein top metal feature 34T is exposed. The respective process is illustrated as process 204 in the process flow 200 as shown in FIG. 36.

Next, as shown in FIG. 17, metal seed layer (which is also a barrier) 45A is deposited, which may comprise a titanium layer and a copper layer over the titanium layer. The respective process is illustrated as process 206 in the process flow 200 as shown in FIG. 36. A patterned photoresist 47 is then formed. The respective process is illustrated as process 208 in the process flow 200 as shown in FIG. 36. Referring to FIG. 18, a plating process is performed to deposit a metallic material 45B such as copper. The respective process is illustrated as process 210 in the process flow 200 as shown in FIG. 36. The resulting top surface of metallic material 45B may be rounded, as shown in FIG. 13. Alternatively, the metallic material 45B may comprise aluminum, which may have the planar top surface as shown in FIG. 12.

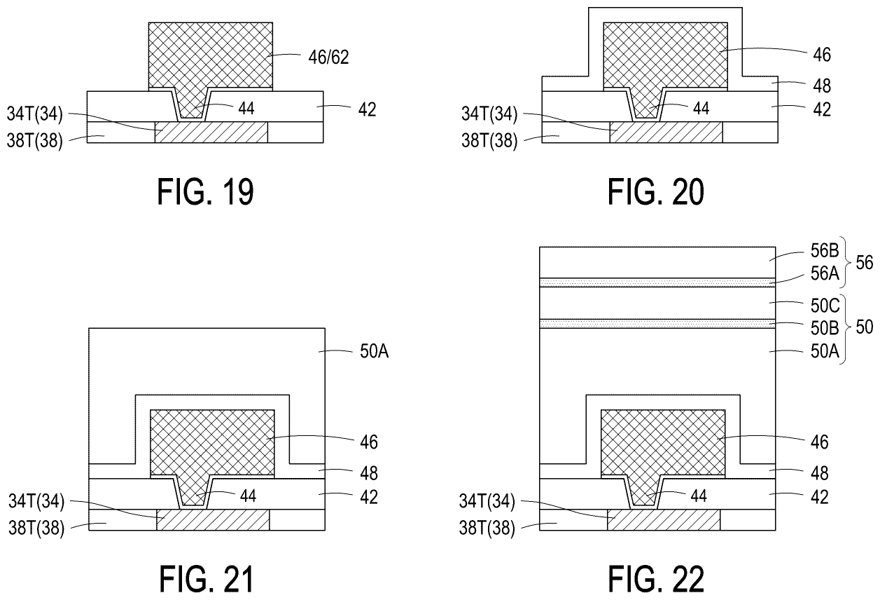

In a subsequent process, photoresist 47 is removed to reveal the underlying portions of metal seed layer 45A. The revealed metal seed layer 45A is then removed through etching. The respective process is illustrated as process 212 in the process flow 200 as shown in FIG. 36. The remaining portions of the metal seed layer 45A and the metallic material 45B collectively form via 44 and RDL 46, which are shown in FIG. 19 and are also shown in FIG. 1. RDL 46 may be used to form passive device 62 and the RDLs and metal pads in functional circuit zone 58F.

Next, as shown in FIG. 20, passivation layer 48 is deposited, for example, using a material comprising silicon nitride, silicon oxide, or the like. The respective process is illustrated as process 214 in the process flow 200 as shown in FIG. 36. Passivation layer 48 may be formed as a conformal layer, for example, through a conformal deposition process such as ALD, CVD, or the like.

Referring to FIG. 21, dielectric layer 50A, which is also referred to as a planarization layer, is deposited. Dielectric layer 50A may be a polymer layer formed of polyimide, PBO, or the like. The respective process is illustrated as process 216 in the process flow 200 as shown in FIG. 36. In FIG. 22, a plurality of dielectric layers are deposited. The respective process is illustrated as process 218 in the process flow 200 as shown in FIG. 36. The plurality of dielectric layers may comprise dielectric layers 50B, 50C, 56A, and 56B. In accordance with some embodiments, dielectric layers 50B, 50C, 56A, and 56B may comprise silicon nitride, silicon oxide, respectively, while other materials may be used. Dielectric layers 50A, 50B, and 50C are collective referred to as dielectric layer 50. Dielectric layers 56A and 56B are collectively referred to as dielectric layer 56, which is also referred to as a bond film in accordance with some embodiments.

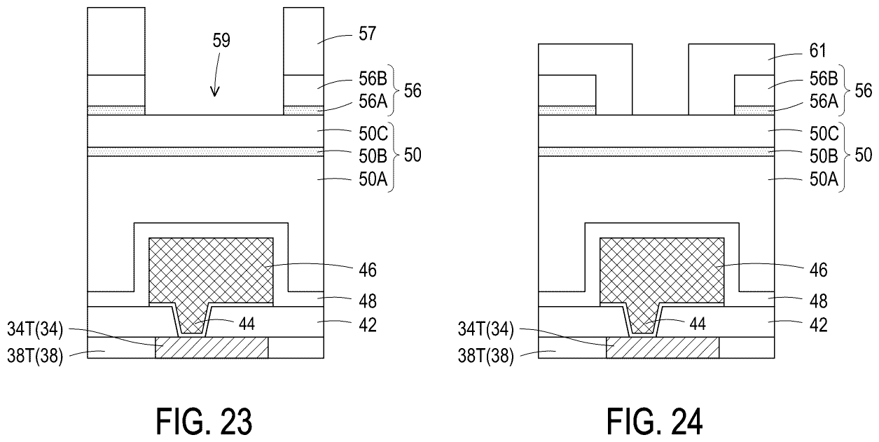

Referring to FIG. 23, a patterned photoresist 57 is formed. Dielectric layers 56B and 56A are etched using the patterned photoresist 57 as an etching mask, so that trench 59 is formed. The respective process is illustrated as process 220 in the process flow 200 as shown in FIG. 36. The etching of dielectric layer 56B may be performed using dielectric layer 56A as an etch stop layer, which is then etched-through. The patterned photoresist 57 is then removed.

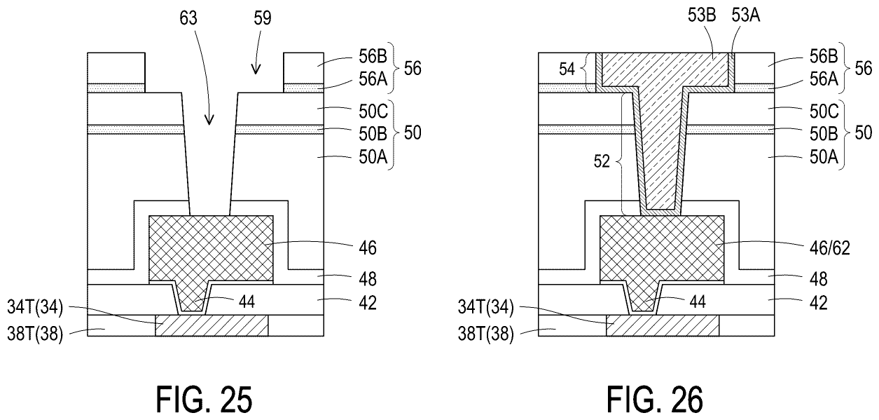

FIGS. 24 and 25 illustrate the formation of via opening 63 in accordance with some embodiments. Referring to FIG. 24, a patterned photoresist 61 is formed. Dielectric layers 50C, 50B, and 50A and passivation layer 48 are etched using the patterned photoresist 61 as an etching mask, so that via opening 63 is formed. The respective process is illustrated as process 222 in the process flow 200 as shown in FIG. 36. The resulting structure is shown in FIG. 25. The patterned photoresist 61 is then removed.

In a subsequent process, as shown in FIG. 26, via 52 and bond pad 54 are formed. The bond pad 54 represents the bond pads 54P, 54T, and 54F as shown in FIG. 1. The respective process is illustrated as process 224 in the process flow 200 as shown in FIG. 36. The formation process may include depositing barrier 53A and metallic material 53B, followed by a planarization process to remove the excess portions of the deposited barrier 53A and metallic material 53B.

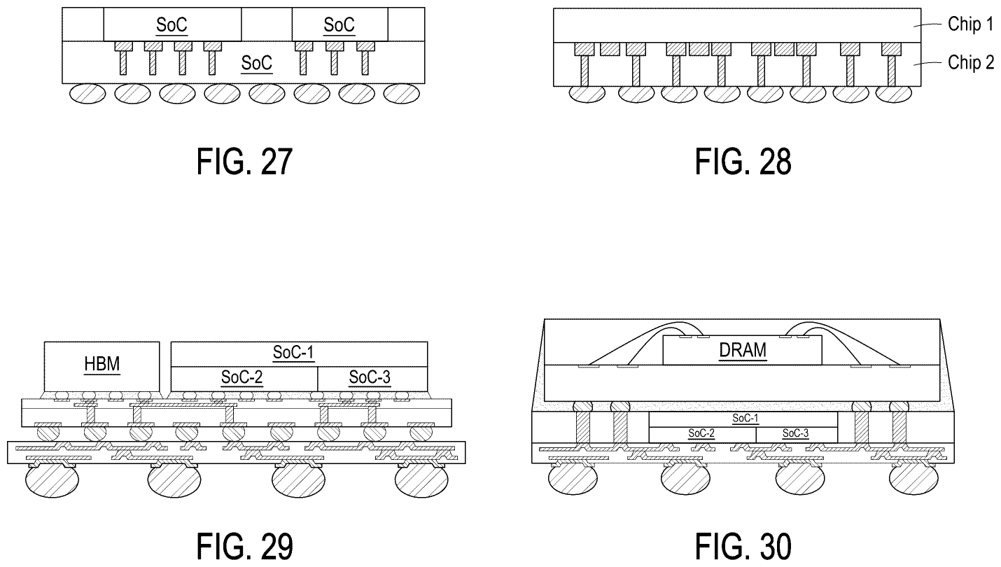

FIGS. 27 through 35 illustrate some packages in which the device die 20′ may be used. FIG. 27 illustrates a structure, in which two system-on-chip (SOC) packages are bonded to an underlying SoC package through chip-on-wafer bonding. One or more of the three packages may include the device die 20′ as shown in FIG. 1 in any combination.

FIG. 28 illustrates two chips chip1 and chip2 bonded through wafer-to-wafer bonding, and hence after the sawing, the edges of the chips chip1 and chip2 are vertically aligned. Either one or both of the chips chip1 and chip2 may adopt the structure of device die 20′ in any combination.

FIG. 29 illustrates a High Bandwidth Memory (HBM) and another package bonding to an interposer. The package includes SoC package SoC-1 bonding to two SoC packages SoC-2 and SoC-3. The interposer is further bonded to a package substrate. One or more, or all of SoC package SoC-1, SoC-2, and SoC-3 may adopt the structure of device die 20′ in any combination.

FIG. 30 illustrates a package including a top package bonding to a bottom package. The top package may include Dynamic Random-Access Memory (DRAM) dies bonding to a package substrate. The bottom package may be an Integrated Fanout (InFO) package including another package therein, with the other package including SoC packages SoC-1, SoC-2, and SoC-3. One or more, or all of SoC package SoC-1, SoC-2, and SoC-3 may adopt the structure of device die 20′ in any combination.

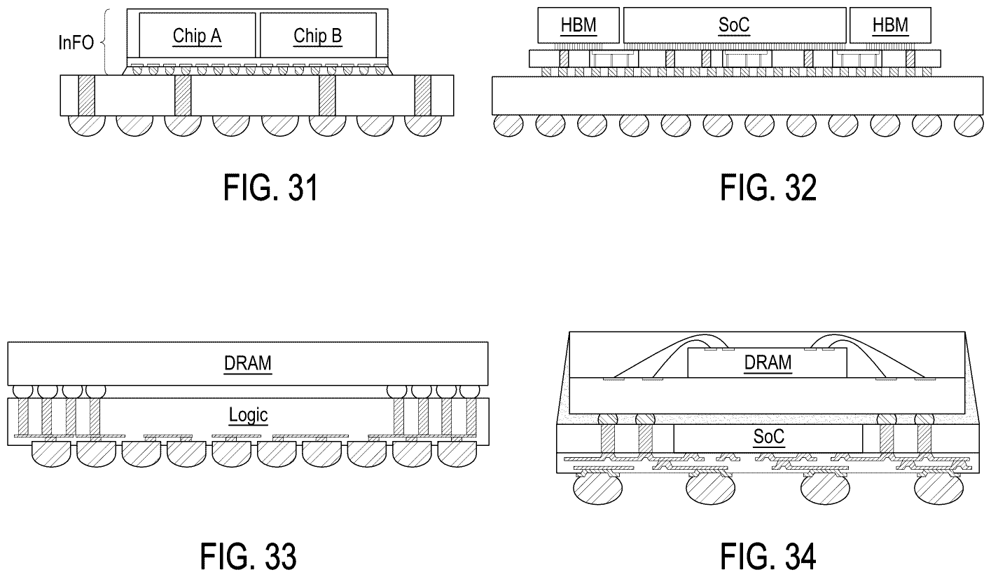

FIG. 31 illustrates a package including two chips chipA and chipB bonding to a package substrate. Either one or both of chips chipA and chipB may adopt the structure of device die 20′ in any combination.

FIG. 32 illustrates a package including an SoC package and two HBMs bonding to an InFO package, which is further on a package substrate. The InFO package may include passive device dies and bridge dies. The SoC package may adopt the structure of device die 20′.

FIG. 33 illustrates a package including a DRAM package bonded to an InFO package. The InFO package may include a logic device die. The logic device die may adopt the structure of device die 20′.

FIG. 34 illustrates a package including an InFO package, which includes a top package bonding to a bottom package. The bottom package, which has the InFO structure, includes a SoC package, which may include the structure of device die 20′.

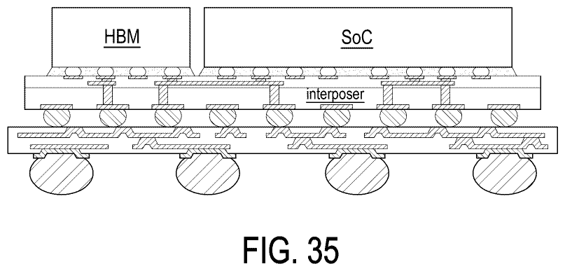

FIG. 35 illustrates a package including an InFO package, which includes a top package bonding to a bottom package. This structure is similar to the structure shown in FIG. 29, except in the structure shown in FIG. 35, there is a single SoC package (rather than three SoC packages), which may include the structure of device die 20′.

The embodiments of the present disclosure have some advantageous features. By reducing the pattern density of the bond pads in the passive device region, the adverse impact of the bond pads to the circuit is reduced. The difference in the pattern densities, however, may incur pattern loading effect. By making the bond pads in transition zone to have a pattern density between the pattern densities of the bond pads in the passive device zone and functional circuit zone, the pattern loading effect may be reduced.

In accordance with some embodiments, a method comprises forming a function circuit on a semiconductor substrate of a device die, wherein the function circuit is in a functional circuit zone of the device die; forming a passive device over the semiconductor substrate, wherein the passive device is in a passive device zone of the device die; forming a first plurality of bond pads in the functional circuit zone and at a surface of the device die, wherein the first plurality of bond pads have a first pattern density; and forming a second plurality of bond pads in the passive device zone and at the surface of the device die, wherein the second plurality of bond pads have a second pattern density lower than the first pattern density.

In an embodiment, the method further comprises forming a third plurality of bond pads in a transition zone and at the surface of the device die, wherein the transition zone is between the passive device zone and the functional circuit zone, and wherein the third plurality of bond pads have a third pattern density lower than the first pattern density. In an embodiment, the third plurality of bond pads is greater than the second pattern density. In an embodiment, the third plurality of bond pads are dummy pads. In an embodiment, the transition zone has a ring shape encircling the passive device zone. In an embodiment, the third pattern density is gradient, with pattern densities in portions of the transition zone closer to the passive device zone being lower than densities in portions of the transition zone closer to the functional circuit zone.

In an embodiment, the forming the passive device comprises forming an inductor, and wherein the forming the inductor comprises forming and interconnecting a plurality of redistribution lines. In an embodiment, the method further comprises bonding the device die to a package component, wherein the first plurality of bond pads and the second plurality of bond pads are physically bonded to additional bond pads of the package component. In an embodiment, the forming the first plurality of bond pads and the forming the second plurality of bond pads comprise forming a dielectric layer; etching the dielectric layer to form a plurality of openings; filling a conductive material in the plurality of openings; and performing a planarization process to level top surfaces of the dielectric layer and the conductive material, wherein remaining portions of the conductive material comprise the first plurality of bond pads and the forming the second plurality of bond pads.

In accordance with some embodiments, a structure comprises a device die comprising a functional circuit zone; a first plurality of bond pads in the functional circuit zone, wherein the functional circuit zone has a first pattern density of bond pads; a functional circuit in the functional circuit zone and underlying the first plurality of bond pads; a passive device zone; a passive device in the passive device zone; a second plurality of bond pads in the passive device zone and over the passive device, wherein the passive device zone has a second pattern density of bond pads, and the second pattern density is lower than the first pattern density; a transition zone between the functional circuit zone and the passive device zone; and a third plurality of bond pads in the transition zone, wherein the transition zone has a third pattern density of bond pads, and the third pattern density is lower than the first pattern density and greater than the second pattern density.

In an embodiment, the second plurality of bond pads comprises electrically floating bond pads. In an embodiment, the third plurality of bond pads are electrically floating. In an embodiment, the transition zone comprises a plurality of sub zones, and wherein first ones of the plurality of sub zones that are closer to the passive device zone have lower pattern densities than respective second ones of the plurality of sub zones that are closer to the functional circuit zone.

In an embodiment, the transition zone is free from active devices therein. In an embodiment, the passive device comprises an inductor. In an embodiment, the structure further comprises a package component bonding to the device die, wherein the first plurality of bond pads, the second plurality of bond pads, and the third plurality of bond pads are in physical contact with, and are joined to, the package component.

In accordance with some embodiments, a structure comprises a semiconductor substrate; a plurality of metal layers over the semiconductor substrate; an inductor over the plurality of metal layers; a first plurality of bond pads, wherein a first chip area occupied by the first plurality of bond pads overlaps the inductor, and the first plurality of bond pads have a first pitch; a second plurality of bond pads in a second chip area encircling the first plurality of bond pads, wherein the second plurality of bond pads have a second pitch smaller than the first pitch; and a third plurality of bond pads in a third chip area encircling the second plurality of bond pads, wherein the third plurality of bond pads have a third pitch smaller than the second pitch.

In an embodiment, the first plurality of bond pads have a first pattern density, and wherein the second plurality of bond pads have a second pattern density greater than the first pattern density, and the third plurality of bond pads have a third pattern density greater than the second pattern density. In an embodiment, the first plurality of bond pads have a first lateral dimension, and wherein the second plurality of bond pads have a second lateral dimension greater than the first lateral dimension, and the third plurality of bond pads have a third lateral dimension greater than the second lateral dimension.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a function circuit on a semiconductor substrate of a device die, wherein the function circuit is in a functional circuit zone of the device die;
forming a passive device over the semiconductor substrate, wherein the passive device is in a passive device zone of the device die;
forming a first plurality of bond pads in the functional circuit zone and at a surface of the device die, wherein the first plurality of bond pads have a first pattern density;
forming a second plurality of bond pads in the passive device zone and at the surface of the device die, wherein the second plurality of bond pads have a second pattern density lower than the first pattern density; and
forming a third plurality of bond pads in a transition zone and at the surface of the device die, wherein the transition zone is between the passive device zone and the functional circuit zone, wherein the third plurality of bond pads have a third pattern density lower than the first pattern density, wherein forming the passive device comprises forming an inductor, and wherein the forming the inductor comprises forming and interconnecting a plurality of redistribution lines.
